(19) United States
(12) Patent Application Publication
(10) Pub. No.: US 2024/0138060 A1
(43) Pub. Date: Apr. 25, 2024

(54) PRINTED CIRCUIT BOARD AND ELECTRONIC DEVICE

(71) Applicant: HUAWEI TECHNOLOGIES CO., LTD., Shenzhen (CN)

(72) Inventors: Wei TAO, Dongguan (CN); Yupeng JIN, Dongguan (CN); Yalei SANG, Dongguan (CN); Zhenyu CHEN, Dongguan (CN); Wusiman ZAIMURAN, Shenzhen (CN)

(21) Appl. No.: 18/400,022

(22) Filed: Dec. 29, 2023

Related U.S. Application Data
(63) Continuation of application No. PCT/CN2021/103976, filed on Jul. 1, 2021.

(51) Int. Cl. H05K 1/03; H05K 1/02; H05K 1/11; H05K 3/46

(52) U.S. Cl. CPC H05K 1/0393; H05K 1/0298; H05K 1/115; H05K 3/4602; H05K 3/4623

(57) ABSTRACT

Embodiments of this application provide a printed circuit board, including a core board and a substrate. The core board covers and is disposed on an outer surface of the substrate. The core board includes a first conductive layer, a second conductive layer, and a first dielectric layer. The first conductive layer is located on a side that is of the core board and that is away from the substrate, the second conductive layer is located on a side that is of the core board and that is close to the substrate, and the first dielectric layer is located between the first conductive layer and the second conductive layer, and includes a flexible dielectric layer whose Young's modulus is less than or equal to a preset Young's modulus.

### CROSS-REFERENCE TO RELATED APPLICATIONS

This application is a continuation of International Application No. PCT/CN2021/103976, filed on Jul. 1, 2021, the disclosure of which is hereby incorporated by reference in its entirety.

### TECHNICAL FIELD

This application relates to the field of printed circuit boards, and in particular, to a printed circuit board and an electronic device.

### BACKGROUND

As energy products evolve toward high power and high density, a quantity of layers and a copper thickness of a printed circuit board (PCB) of an energy product increase, causing an increase in a coefficient of thermal expansion (CTE) and a Young's modulus of the printed circuit board. Consequently, the challenge of reliability of solder joints of high-power devices is increasing. A conventional PCB board material cannot meet a test requirement of long-term reliability of solder joints, and a solder joint crack problem is prone to occur.

### SUMMARY

Embodiments of this application provide a printed circuit board and an electronic device, to reduce a Young's modulus of a printed circuit board and improve reliability of a solder joint between a power device and the PCB.

According to a first aspect, an embodiment of this application provides a printed circuit board, including a core board and a substrate. The core board covers and is disposed on one of two opposing outer surfaces of the substrate. The core board includes a first conductive layer, a second conductive layer, and a first dielectric layer. The first conductive layer is located on a side that is of the core board and that is away from the substrate, the second conductive layer is located on a side that is of the core board and that is close to the substrate, and the first dielectric layer is located between the first conductive layer and the second conductive layer, and includes a flexible dielectric layer whose Young's modulus is less than or equal to a preset Young's modulus.

In the printed circuit board provided in this embodiment of this application, the flexible dielectric layer is hybridly laminated at a dielectric layer between an outermost conductive layer and a secondary outer conductive layer, to reduce a Young's modulus of the dielectric layer between the outermost conductive layer and the secondary outer conductive layer. A modulus of the PCB at the bottom of a solder joint of a power device is reduced, thereby improving reliability of the solder joint between the power device and the PCB and meeting a service life requirement of a product. In addition, a voltage withstanding capability between the outermost conductive layer and the secondary outer conductive layer is enhanced.

In a possible implementation, the preset Young's modulus is less than or equal to 15 GPa.

In another possible implementation, the core board also covers and is disposed on the other outer surface of the two opposing outer surfaces of the substrate.

In another possible implementation, the first dielectric layer further includes a prepreg (prepreg, PP), and the first dielectric layer is formed through hybrid lamination on the flexible dielectric layer and the prepreg.

In an example, the prepreg partially or completely covers a surface that is of the flexible dielectric layer and that is close to the second conductive layer. A surface that is of the flexible dielectric layer and that is close to the first conductive layer is closely attached to the first conductive layer, and the prepreg is closely attached to both the flexible dielectric layer and the second conductive layer. In this way, the first conductive layer and the flexible dielectric layer are first laminated to make a single-sided board, and then the single-sided board and an inner-layer core board are bonded by using the prepreg to form a PCB motherboard.

In another example, both the surface that is of the flexible dielectric layer and that is close to the first conductive layer and the surface that is of the flexible dielectric layer and that is close to the second conductive layer partially or completely cover the prepreg. The flexible dielectric layer is closely connected to both the first conductive layer and the second conductive layer by using the prepreg.

Optionally, the prepreg is an FR4 prepreg.

In another possible implementation, the surface that is of the flexible dielectric layer and that is close to the first conductive layer is closely attached to the first conductive layer, and the surface that is of the flexible dielectric layer and that is close to the second conductive layer is closely attached to the second conductive layer.

In another possible implementation, a pad is disposed at the first conductive layer, and the flexible dielectric layer is disposed at a position that corresponds to the pad and is at the first dielectric layer.

In a possible implementation, the substrate includes N third conductive layers and M second dielectric layers, and the third conductive layers and the second dielectric layers are alternately stacked, where N=M+1, both N and M are natural numbers, and a Young's modulus of the first dielectric layer is less than a Young's modulus of the second dielectric layer. In another possible implementation, the substrate includes N third conductive layers and M second dielectric layers, and the third conductive layers and the second dielectric layers are alternately stacked, where M=N+1, both N and M are natural numbers, and a part of the M second dielectric layers includes the flexible dielectric layer, or each of the M second dielectric layers includes the flexible dielectric layer.

In another possible implementation, a coefficient of thermal expansion of the flexible dielectric layer in an X-axis direction and a Y-axis direction is less than or equal to a preset threshold.

Optionally, the preset threshold is less than or equal to 30.

In the printed circuit board provided in this embodiment of this application, the flexible dielectric layer whose Young's modulus is less than the preset Young's modulus and whose CTE in the X-axis direction and the Y-axis direction is less than the preset threshold is hybridly laminated at the dielectric layer between the outermost conductive layer and the secondary outer conductive layer, so that both the Young's modulus and the CTE of the PCB are reduced, and reliability of the solder joint between the power device and the PCB is further improved.

Optionally, the flexible dielectric layer is made of a polyimide material.

According to a second aspect, an embodiment of this application further provides an electronic device, including a power device and the printed circuit board provided in the first aspect. The power device is electrically connected to the printed circuit board, and a service life of the electronic device is prolonged.

### BRIEF DESCRIPTION OF DRAWINGS

FIG. 1 is a schematic diagram of a structure of a printed circuit board according to an embodiment of this application;

FIG. 2 is a flowchart of manufacturing the printed circuit board shown in FIG. 1 according to an embodiment of this application;

FIG. 3 is a schematic diagram of a structure of another printed circuit board according to an embodiment of this application;

FIG. 4 is a flowchart of manufacturing the printed circuit board shown in FIG. 3 according to an embodiment of this application;

FIG. 5 is a schematic diagram of a structure of another printed circuit board according to an embodiment of this application; and

FIG. 6 is a flowchart of manufacturing the printed circuit board shown in FIG. 5 according to an embodiment of this application.

### DESCRIPTION OF EMBODIMENTS

The following describes technical solutions in embodiments of this application with reference to accompanying drawings in embodiments of this application.

In descriptions of this application, locations or location relationships indicated by terms “center”, “up”, “down”, “in front of”, “behind”, “left”, “right”, “vertical”, “horizontal”, “top”, “bottom”, “inside”, “outside”, and the like are based on locations or location relationships shown in the accompanying drawings, and are merely intended for ease of describing this application and simplifying descriptions, instead of indicating or implying that a mentioned apparatus or component needs to be provided on a specific location or constructed and operated on a specific location, and therefore shall not be understood as limitations on this application.

In the descriptions of this application, it should be noted that, unless otherwise clearly specified and limited, terms “mount”, “link”, and “connect” should be understood in a broad sense, for example, may mean a fixed connection, may be a detachable connection, or may be a butt joint connection or an integrated connection. A person of ordinary skill in the art can understand specific meanings of the foregoing terms in this application based on specific cases.

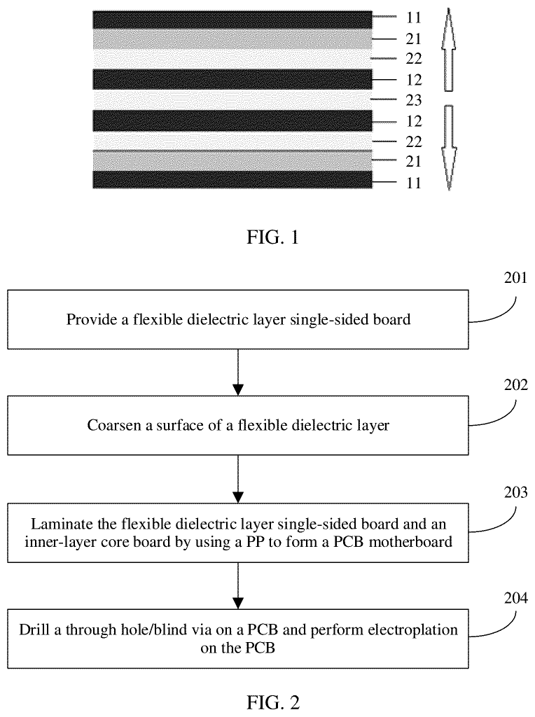

This application provides a printed circuit board. The printed circuit board is of a laminated structure, including a plurality of conductive layers and dielectric layers that are alternately stacked. As shown in FIG. 1, the conductive layers may include four layers (for example, two first conductive layers 11 and two second conductive layers 12 in FIG. 1), and the dielectric layers may include three layers (for example, two first dielectric layers (including a flexible dielectric layer 21 and a PP layer 22) in FIG. 1 and a central dielectric layer 23 (core) located at the central layer of the laminated structure). Certainly, FIG. 1 shows only a possible structure of the printed circuit board. A quantity of conductive layers and a quantity of dielectric layers may be set based on an actual requirement. The quantity of conductive layers and the quantity of dielectric layers are not limited in this application.

The conductive layers and the dielectric layers are alternately stacked, and the conductive layer is disposed on an upper surface of the dielectric layer.

Generally, an outer surface of a PCB is a side surface that is of the PCB and that is used to dispose a pad or solder a power device. The upper surface of the dielectric layer is a side surface that is of the dielectric layer and that is close to the outer surface of the PCB, and a lower surface of the dielectric layer is a side surface that is of the dielectric layer and that is away from the outer surface of the PCB.

The conductive layer is made of a conductive material. The conductive material is usually a conductor with relatively good conductive performance, such as copper, aluminum, or silver. The conductive layer may be connected to a ground cable to shield and protect a signal.

The dielectric layer is made of an insulation material, and therefore is usually also referred to as an insulation layer. The dielectric layer mainly plays a role of supporting the conductive layer.

Still refer to FIG. 1. The first conductive layer 11 and the second conductive layer 12 are respectively an outermost conductive layer and a secondary outer conductive layer of the plurality of conductive layers of the laminated structure. In other words, the first conductive layer 11 and the second conductive layer 12 are respectively the outermost conductive layer and the secondary outer conductive layer of the plurality of conductive layers in a direction (that is, an arrow direction in FIG. 1) away from the core layer 23.

The first dielectric layer is located between the first conductive layer 11 and the second conductive layer 12.

It is easy to understand that the direction away from the core layer 23 has two opposing directions (referring to arrow directions in the figure) with the core layer 23 as a start point. Therefore, there are two first conductive layers 11 and two second conductive layers 12, and there are also two first dielectric layers.

The first dielectric layer includes the flexible dielectric layer 21 whose Young's modulus is less than or equal to a preset Young's modulus.

Optionally, the preset Young's modulus is less than or equal to 15 GPa. In other words, the Young's modulus of the flexible dielectric layer is less than or equal to 15 GPa.

In the printed circuit board provided in this embodiment of this application, the flexible dielectric layer is hybridly laminated at the dielectric layer between the outermost conductive layer and the secondary outer conductive layer, to reduce a Young's modulus of the dielectric layer between the outermost conductive layer and the secondary outer conductive layer. A modulus of the PCB at the bottom of a solder joint of the power device is reduced, thereby improving reliability of the solder joint between the power device and the PCB and meeting a service life requirement of a product. In addition, a voltage withstanding capability between the outermost conductive layer and the secondary outer conductive layer is enhanced.

In an example, the first dielectric layer is formed through hybrid lamination on the PP layer and the flexible dielectric layer. Because the Young's modulus of the flexible dielectric layer is less than a Young's modulus of the PP layer, a Young's modulus of the first dielectric layer obtained through hybrid lamination on the PP layer and the flexible dielectric layer is also less than the Young's modulus of the PP layer, so that the Young's modulus of the first dielectric layer is effectively reduced.

For example, in FIG. 1, the PP layer 22 includes a PP that partially or completely covers a surface that is of the flexible dielectric layer 21 and that is close to the second conductive layer 12. A surface that is of the flexible dielectric layer 21 and that is close to the first conductive layer is closely attached to the first conductive layer 11, and the PP is closely attached to both the flexible dielectric layer 21 and the second conductive layer 12, to firmly bond the flexible dielectric layer 21 and the second conductive layer 12.

The PP is an interlayer adhesive. With the help of a high temperature and high pressure environment of a lamination machine, the PP is first softened and then hardened, and changes from a B-stage to a C-stage to make two layers bonded by using the PP as an integrated one. For example, in FIG. 1, the PP bonds the flexible dielectric layer 21 and the second conductive layer 12 as an integrated one.

The PP may be made of a thermally cured or thermoplastic material, for example, a phenolic aldehyde resin, a urea-formaldehyde resin, a melamine resin, an unsaturated polyester resin, an epoxy resin, an organic silicone resin, or polyurethane. This is not limited in this application. A proper material may be selected to prepare the PP based on a requirement.

FIG. 2 is a flowchart of manufacturing the printed circuit board shown in FIG. 1 according to an embodiment of this application. As shown in FIG. 2, a process of manufacturing the printed circuit board shown in FIG. 1 includes step S201 to step S204.

Step S201: Provide a flexible dielectric layer single-sided board, where the flexible dielectric layer single-sided board includes a flexible dielectric layer and a conductive layer formed on a surface of the flexible dielectric layer, for example, a copper foil layer.

Step S202: Coarsen a surface of the flexible dielectric layer, so that the flexible dielectric layer single-sided board is more easily bonded and fixed to an inner-layer core board.

Step S203: Laminate the flexible dielectric layer single-sided board and the inner-layer core board by using the PP to form a PCB motherboard.

For example, the flexible dielectric layer single-sided board (a side that is of the flexible dielectric layer single-sided board and that is away from the conductive layer is disposed towards the PP), the PP, the inner-layer core board, the PP, and the flexible dielectric layer single-sided board are sequentially stacked and laminated to form the PCB motherboard.

In this step, a laminated structure formed by stacking the flexible dielectric layer single-sided board, the PP, the inner-layer core board, the PP, and the flexible dielectric layer single-sided board may be coated with an adhesive-resistant release film, and then a lamination operation is performed, to avoid a phenomenon of a PP outflow because the PP is melted into glue during a lamination process.

It is easy to understand that the inner-layer core board is a core board located at an inner layer of the PCB, for example, the core layer 23 and the second conductive layers 12 respectively covering the upper and lower surfaces of the core layer 23 in FIG. 1.

Step S204: Drill a through hole/blind via on the PCB and perform electroplation on the PCB to implement conduction between the conductive layers.

A via is drilled on at least one dielectric layer and one conductive layer along a stacking direction of the dielectric layer and the conductive layer. When no via is drilled at a dielectric layer and a conductive layer, a blind via is formed on the PCB. When a via is drilled at each dielectric layer and each conductive layer, a through hole through the PCB is formed on the PCB.

The blind via is generally used to connect a surface trace and an inner trace below. Generally, a ratio of a depth of the via to a diameter of the via does not exceed a specific ratio.

The through hole is generally used for internal interconnection or used as a positioning hole for mounting a component and a device.

The via is configured to conduct traces located at different layers, the via is filled with a material medium to form a via core, and the via core is insulated from the conductive layer and is electrically connected to a trace that needs to be conducted.

The via may be separately disposed, and the via core in the via is electrically connected to another structure, for example, a pad disposed at the conductive layer, by using a trace. In addition, a pad may be directly disposed on the via, and then the power device is soldered on the pad, so that the power device can also be electrically connected to the via core in the via. The power device may be, for example, an electrical component such as a MOS transistor or a chip.

During implementation, the via core and the conductive layer may be disposed at an interval to implement insulation between the via core and the conductive layer. Alternatively, the insulation material may be disposed between the via core and the conductive layer, for example, an insulating resin is coated or insulating rubber is disposed, to implement insulation between the via core and the conductive layer.

A hole forming process such as plasma hole forming, photosensitive hole forming, and laser hole forming may be selected as a hole drilling process of the through hole or the blind via. This is not limited in this embodiment of this application. A proper hole forming process may be selected based on an actual situation.

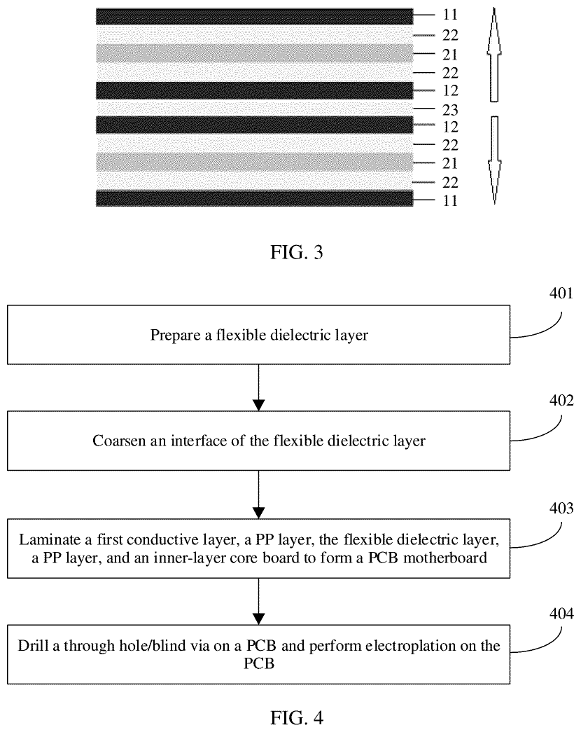

FIG. 3 is a schematic diagram of a structure of another printed circuit board according to an embodiment of this application. As shown in FIG. 3, a difference from the printed circuit board shown in FIG. 1 lies in that, a first dielectric layer includes PP layers 22 that cover and are disposed on an upper surface and a lower surface of a flexible dielectric layer 21. The PP layer 22 includes a PP that partially or completely covers the upper surface or the lower surface of the flexible dielectric layer 21, and the flexible dielectric layer 21 is closely connected to a first conductive layer and a second conductive layer by using the PP.

It should be explained that the upper surface of the flexible dielectric layer 21 is a surface of a side that is of the flexible dielectric layer and that is close to the first conductive layer 11, and the lower surface of the flexible dielectric layer is a surface of a side that is of the flexible dielectric layer and that is close to the second conductive layer 12. In other words, the upper surface of the flexible dielectric layer is a surface of a side that is of the flexible dielectric layer and that is away from a core layer 23, and the lower surface of the flexible dielectric layer is a surface of a side that is of the flexible dielectric layer and that is close to the core layer 23.

In an example, the PP mentioned above is an FR4 PP.

FIG. 4 is a flowchart of manufacturing the printed circuit board shown in FIG. 3 according to an embodiment of this application. As shown in FIG. 4, a process of manufacturing the printed circuit board shown in FIG. 3 includes step S401 to step S404.

Step S401: Prepare the flexible dielectric layer.

That is, a flexible dielectric material is made into a plate-like structure. For example, the flexible dielectric material is laminated into a plate-like flexible dielectric layer.

Step S402: Coarsen a surface of the flexible dielectric layer.

Both the upper and lower surfaces of the flexible dielectric layer are coarsened, so that the flexible dielectric layer is more easily bonded and fixed to the PP.

Step S403: Laminate the first conductive layer, a PP layer, the flexible dielectric layer, a PP layer, and an inner-layer core board to form a PCB motherboard.

For example, the first conductive layer, the PP layer, the flexible dielectric layer, the PP layer, the inner-layer core board, the PP layer, the flexible dielectric layer, the PP layer, and the first conductive layer are sequentially stacked and laminated to form the PCB motherboard.

A sandwich structure of the PP layer, the flexible dielectric layer, and the PP layer are formed at the first dielectric layer.

It is easy to understand that the inner-layer core board is a core board located at an inner layer of the PCB, for example, the core layer 23 and the second conductive layers 12 respectively covering the upper and lower surfaces of the core layer 23 in FIG. 3.

Step S404: Drill a through hole/blind via on the PCB and perform electroplation on the PCB to implement conduction between the conductive layers.

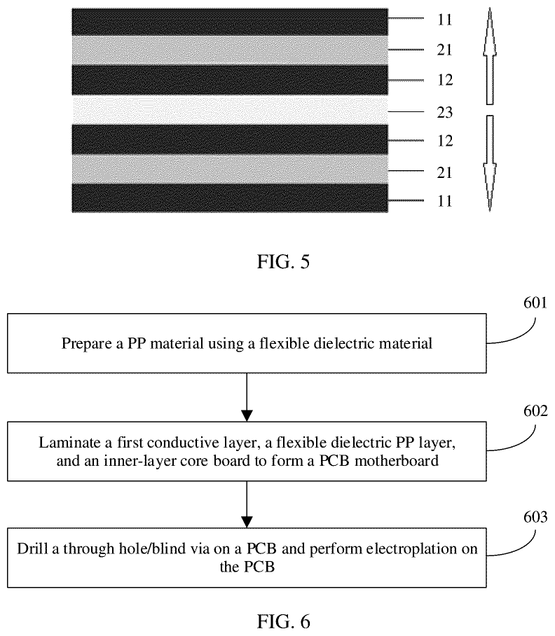

FIG. 5 is a schematic diagram of a structure of another printed circuit board according to an embodiment of this application. As shown in FIG. 5, a difference from the printed circuit boards shown in FIG. 1 and FIG. 3 lies in that a first dielectric layer includes only a flexible dielectric layer, and an upper surface and a lower surface of the flexible dielectric layer are respectively closely attached to a first conductive layer and a second conductive layer.

It should be explained that the upper surface of the flexible dielectric layer 21 is a surface of a side that is of the flexible dielectric layer 21 and that is close to the first conductive layer 11, and the lower surface of the flexible dielectric layer 21 is a surface of a side that is of the flexible dielectric layer 21 and that is close to the second conductive layer 12. In other words, the upper surface of the flexible dielectric layer 21 is a surface of a side that is of the flexible dielectric layer 21 and that is away from a core layer 23, and the lower surface of the flexible dielectric layer 21 is a surface of a side that is of the flexible dielectric layer 21 and that is close to the core layer 23.

FIG. 6 is a flowchart of manufacturing the printed circuit board shown in FIG. 5 according to an embodiment of this application. As shown in FIG. 6, a process of manufacturing the printed circuit board shown in FIG. 5 includes step S601 to step S603.

Step S601: Prepare a PP material using a flexible dielectric material.

That is, a dielectric material whose Young's modulus is less than 15 GPa is selected to prepare the PP material. For example, a polyimide (polyimide, PI) material is selected to prepare the PP material.

Step S602: Laminate the first conductive layer, a flexible dielectric PP layer, and an inner-layer core board to form a PCB motherboard.

For example, the first conductive layer, the flexible dielectric PP layer, the inner-layer core board, the flexible dielectric PP layer, and the first conductive layer are sequentially stacked and laminated to form the PCB motherboard.

It is easy to understand that the inner-layer core board is a core board located at an inner layer of the PCB, for example, the core layer 23 and the second conductive layers 12 respectively covering the upper and lower surfaces of the core layer 23 in FIG. 5.

Step S603: Drill a through hole/blind via on the PCB and perform electroplation on the PCB to implement conduction between the conductive layers.

It may be understood that the manufacturing processes provided in FIG. 2, FIG. 4, and FIG. 6 for the printed circuit boards in FIG. 1, FIG. 3, and FIG. 5 in embodiments of this application are partial manufacturing processes. For example, after step S204, step S404, or step S603, subsequent manufacturing steps such as outer layer imaging, outer layer etching, outer layer inspection, solder mask/silkscreen, surface processing, milling, electrical performance test, final quality control, and packaging are further included.

In an example, the flexible dielectric layer may be hybridly laminated to the entire layer of the first dielectric layer. For example, the flexible dielectric layer is hybridly laminated to the entire layer of the first dielectric layer of the printed circuit board shown in FIG. 1, FIG. 3, or FIG. 5. In this way, reliability of the solder joint between the power device and the PCB is improved by reducing the Young's modulus of the first dielectric layer, and manufacturing and processing of the first dielectric layer are convenient.

In another example, the flexible dielectric layer may be hybridly laminated to a portion of the first dielectric layer. For example, a pad (not shown in the figure) is disposed at the first conductive layer of the printed circuit board shown in FIG. 1, FIG. 3, or FIG. 5, and the flexible dielectric layer is disposed at a position that corresponds to the pad and is at the first dielectric layer.

It should be explained that, the position that corresponds to the pad and is at the first dielectric layer is an area that is at the first dielectric layer and that affects a solder joint when the power device is soldered on the pad. For example, the position that corresponds to the pad and is at the first dielectric layer is an area that is at the first dielectric layer and that is below the pad, an area of orthographic projection of the pad at the first dielectric layer, an area that is slightly larger than orthographic projection of the pad at the first dielectric layer, or an area that is slightly smaller than orthographic projection of the pad at the first dielectric layer. In this way, reliability of the solder joint between the power device and the PCB is improved by reducing the Young's modulus of the first dielectric layer, and the flexible dielectric material is saved.

The pad includes a functional pad and a non-functional/redundant pad, and is configured to implement an electrical connection and a mechanical connection between the power device (such as a MOS transistor and a chip) and the PCB, to correctly package the power device on the PCB.

It is easy to understand that the core board includes the first conductive layer 11, the dielectric layer including the flexible dielectric layer 21 and the PP layer 22, and the second conductive layer in FIG. 1, FIG. 3, or FIG. 5, and the core layer 23 is the substrate. The core boards cover and are disposed on two opposing outer surfaces of the substrate in extension directions, to reduce Young's moduli of outer layers on both sides of the PCB and improve reliability of the solder joint between the power device and the PCB.

In another example, to simplify the manufacturing process of the printed circuit board, the core board may be disposed only on one side of the substrate, that is, the core board covers only one outer surface of the substrate in an extension direction, and a conventional core board is still used on the other outer surface. For example, the flexible dielectric layer is disposed at the dielectric layer between the first conductive layer 11 and the second conductive layer only in one arrow direction in FIG. 1, FIG. 3, or FIG. 5.

In an example, the substrate includes N third conductive layers and M second dielectric layers, and the third conductive layers and the second dielectric layers are alternately stacked, where M=N+1, and both N and M are natural numbers. For example, the substrate may be of a single-layer structure, that is, N=0 and M=1. For example, the substrate in FIG. 1, FIG. 3, and FIG. 5 only has one dielectric layer, that is, the core layer 23. Alternatively, the substrate may be of a multi-layer structure. For example, N=1 and M=2. That is, the substrate has one conductive layer and two dielectric layers, and the dielectric layers and the conductive layer are alternately stacked to form the multi-layer structure. A structure of the substrate may be selected based on a requirement. A specific structure of the substrate is not limited in this application.

To save the flexible dielectric material, the dielectric layer (that is, the second dielectric layer) in the substrate is made of a conventional material, for example, an epoxy resin. A Young's modulus of the second dielectric layer is greater than 20 GPa. Therefore, the Young's modulus of the first dielectric layer is less than the Young's modulus of the second dielectric layer.

In another example, the flexible dielectric layer is disposed at all or some dielectric layers of the substrate. The Young's modulus of the PCB is reduced as a whole, and voltage withstanding of the PCB is improved. In addition, board materials of a plurality of core boards in the PCB are the same, ensuring that moduli and CTEs of the plurality of core boards are the same or approximately the same.

Preferably, a thickness of the flexible dielectric layer is 2-8 mil, a thickness of the PP layer is 2-5 mil, and a thickness of the conductive layer is 3-5 oz.

In an example, a CTE of the flexible dielectric layer in X-axis and Y-axis directions is less than or equal to a preset threshold. For example, the preset threshold is less than or equal to 30. In other words, the CTE of the flexible dielectric layer in the X-axis and Y-axis directions is less than or equal to 30.

It is easy to understand that the X-axis and Y-axis directions of the flexible dielectric layer are surface extension directions of the flexible dielectric layer, that is, directions perpendicular to a thickness direction of the flexible dielectric layer.

In this way, the Young's modulus of the flexible dielectric layer needs to be less than or equal to 15 GPa, and the CTE of the flexible dielectric layer in the X-axis and Y-axis directions needs to be less than or equal to 30.

Optionally, the flexible dielectric layer is made of the polyimide (polyimide, PI) material.

In another example, the inner-layer core boards in FIG. 1, FIG. 3, and FIG. 5 may alternatively be of a multi-layer board structure.

An embodiment of this application provides an electronic device, including a power device and the printed circuit board in the foregoing embodiments, and the power device is electrically connected to the printed circuit board.

For example, a pad is disposed at an outermost layer of the printed circuit board, and the power device (for example, a MOS transistor and a chip) is soldered to the pad to electrically connect to a preset trace in the printed circuit board.

Alternatively, a plug hole is disposed on an outer layer of the printed circuit board, and the power device is plugged into the plug hole to electrically connect to the preset trace in the printed circuit board.

The electronic device includes but is not limited to an electronic device, such as a mobile phone, a tablet computer, a wearable device, a notebook computer, an ultra-mobile personal computer (ultra-mobile personal computer, UMPC), a handheld computer, a walkie-talkie, a netbook, a POS machine, a personal digital assistant (personal digital assistant, PDA), an event data recorder, or a virtual reality device.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

What is claimed is:

1. A printed circuit board, comprising: a core board and a substrate, wherein the core board covers and is disposed on one of two opposing outer surfaces of the substrate; and the core board comprises:
a first conductive layer, located on a side that is of the core board and that is away from the substrate;
a second conductive layer, located on a side that is of the core board and that is close to the substrate; and
a first dielectric layer, located between the first conductive layer and the second conductive layer and comprising a flexible dielectric layer, wherein a Young's modulus of the flexible dielectric layer is less than or equal to a preset Young's modulus.

2. The printed circuit board according to claim 1, wherein the preset Young's modulus is less than or equal to 15 GPa.

3. The printed circuit board according to claim 1, wherein the core board also covers and is disposed on the other outer surface of the two opposing outer surfaces of the substrate.

4. The printed circuit board according to claim 1, wherein the first dielectric layer further comprises a prepreg, and the first dielectric layer is formed through hybrid lamination on the flexible dielectric layer and the prepreg.

5. The printed circuit board according to claim 4, wherein the prepreg partially or completely covers a surface that is of the flexible dielectric layer and that is close to the second conductive layer, a surface that is of the flexible dielectric layer and that is close to the first conductive layer is closely attached to the first conductive layer, and the prepreg is closely attached to both the flexible dielectric layer and the second conductive layer.

6. The printed circuit board according to claim 4, wherein both the surface that is of the flexible dielectric layer and that is close to the first conductive layer and the surface that is of the flexible dielectric layer and that is close to the second conductive layer partially or completely cover the prepreg, and the flexible dielectric layer is closely connected to both the first conductive layer and the second conductive layer by using the prepreg.

7. The printed circuit board according to claim 4, wherein the prepreg is an FR4 prepreg.

8. The printed circuit board according to claim 1, wherein the surface that is of the flexible dielectric layer and that is close to the first conductive layer is closely attached to the first conductive layer, and the surface that is of the flexible dielectric layer and that is close to the second conductive layer is closely attached to the second conductive layer.

9. The printed circuit board according to claim 1, wherein a pad is disposed at the first conductive layer, and the flexible dielectric layer is disposed at a position that corresponds to the pad and is at the first dielectric layer.

10. The printed circuit board according to claim 1, wherein the substrate comprises N third conductive layers and M second dielectric layers, the third conductive layers and the second dielectric layers are alternately stacked, M=N+1, and both N and M are natural numbers; and
a Young's modulus of the first dielectric layer is less than a Young's modulus of the second dielectric layer.

11. The printed circuit board according to claim 1, wherein the substrate comprises N third conductive layers and M second dielectric layers, the third conductive layers and the second dielectric layers are alternately stacked, M=N+1, and both N and M are natural numbers; and
a part of the M second dielectric layers comprises the flexible dielectric layer; or
each of the M second dielectric layers comprises the flexible dielectric layer.

12. The printed circuit board according to claim 1, wherein a coefficient of thermal expansion of the flexible dielectric layer in an X-axis direction and a Y-axis direction is less than or equal to a preset threshold.

13. The printed circuit board according to claim 12, wherein the preset threshold is less than or equal to 30.

14. The printed circuit board according to claim 1, wherein the flexible dielectric layer is made of a polyimide material.

15. An electronic device, comprising a power device and the printed circuit board according to claim 1, wherein the power device is electrically connected to the printed circuit board.
